(19) United States
(12) Patent Application Publication
(10) Pub. No.: US 2025/0380446 A1
(43) Pub. Date: Dec. 11, 2025

(54) NITRIDE SEMICONDUCTOR DEVICE AND METHOD OF MANUFACTURING NITRIDE SEMICONDUCTOR DEVICE

(71) Applicant: Mitsubishi Electric Corporation, Tokyo (JP)

(72) Inventors: Yuki TAKIGUCHI, Tokyo (JP); Kunihiko NISHIMURA, Tokyo (JP); Muneyoshi SUITA, Tokyo (JP); Takahiro YAMADA, Tokyo (JP)

(73) Assignee: Mitsubishi Electric Corporation, Tokyo (JP)

(21) Appl. No.: 18/877,314

(22) PCT Filed: Jun. 29, 2022
(86) PCT No.: PCT/JP2022/025969

§ 371 Date: Dec. 20, 2024

(51) Int. Cl. H10D 30/47; H10D 30/01; H10D 62/40; H10D 62/824; H10D 64/27

(52) U.S. Cl. CPC H10D 30/476; H10D 30/015; H10D 62/405; H10D 64/519; H10D 30/475; H10D 62/824

(57) ABSTRACT

Variations in characteristics of a device which are caused by buried gate electrodes are suppressed. A nitride semiconductor device includes: a substrate; a first nitride semiconductor layer; a second nitride semiconductor layer; a source electrode; a drain electrode; at least one blind hole reaching an interior of the first nitride semiconductor layer from an upper surface of the second nitride semiconductor layer; a buried gate electrode inside the blind hole; and a gate finger electrode across an upper surface of the buried gate electrode and the upper surface of the second nitride semiconductor layer, wherein a side surface of the blind hole is along a {1 −1 0 0} plane of the first nitride semiconductor layer.

### TECHNICAL FIELD

The technology disclosed in DESCRIPTION of this present application relates to a nitride semiconductor.

### BACKGROUND ART

Transistors that can operate in a high frequency region include high electron mobility transistors (abbr., HEMTs) using 2-dimensional electron gas (abbr., 2DEG) that is generated in a heterojunction interface of nitride semiconductors each with a wurtzite crystalline structure.

Such nitride semiconductor HEMTs are transistors that can operate at high frequency and at high power with high 2DEG density and with high 2DEG mobility.

Downsizing gate electrodes and shortening channel lengths are effective at increasing power or increasing operations frequency of a HEMT using nitride semiconductors. On the other hand, shortening channel lengths makes short channel effects of worsening the controllability of a drain current at a gate voltage prominent.

For example, Patent Document 1 or Non-Patent Document 1 discloses a semiconductor device that controls the drain current by controlling a channel from two or three directions, using gate electrodes with a buried structure as a structure of suppressing the short channel effects.

### PRIOR ART DOCUMENT

### Patent Document

Patent Document 1: Japanese Unexamined Patent Application Publication No. 2020-526921

### Non-Patent Document

Non-Patent Document 1: Q. Dai et al, “Deep Sub-60 mV/decade Subthreshold Swing in AlGaN/GaN FinMISHFETs with M-Plane Sidewall Channel”, 2019, P1699

### SUMMARY

### Problem to be Solved by the Invention

In each of nitride semiconductor HEMTs, a c-plane ((0 0 0 1) plane) is formed as a main surface, and a channel is formed along the c-plane. Thus, when buried gate electrodes are formed, the gate electrodes are buried vertically in the main surface. In a nitride semiconductor with a wurtzite crystalline structure, an a-plane ({1 1 −2 0} plane) or an m-plane ({1 −1 0 0} plane) that is a crystal plane vertical to the main surface is rotationally symmetric at 60 degrees. Furthermore, the a-plane is lower in chemical resistance than the m-plane in the nitride semiconductor with the wurtzite crystalline structure. Thus, the a-plane has a high etching rate with a solution, and the surface flatness of the a-plane worsens during chemical vapor deposition.

In the semiconductor device disclosed in Patent Document 1 or Non-Patent Document 1, each of the buried gate electrode is round or rectangular in a plan view. In such a structure, crystal planes of side surfaces of holes for forming the buried gate electrodes in a nitride semiconductor do not match. In other words, when each of the buried gate electrodes is rectangular, assuming that one of the side surfaces is the m-plane, a plane facing the m-plane is an m-plane, and two planes not facing the m-plane are a-planes.

When the crystal planes of the side surfaces of the holes in the nitride semiconductor do not match, fabrication variations may occur or the surface flatness may worsen in making the holes for burying the gate electrodes. Furthermore, the surface flatness may worsen in a step after making the holes. These fabrication variations cause dimensional variations in the buried gate electrodes, which are significant in controlling the channel.

The dimensional variations in the gate electrodes lead to threshold voltage fluctuation between the buried gate electrodes, which consequently causes variations in transistor characteristics. Moreover, deterioration in the surface flatness causes reduction in interface properties between the buried gate electrodes and the nitride semiconductor, and reduces effective mobility. In addition, reduction in the adhesion between the buried gate electrodes and the nitride semiconductor reduces the reliability of semiconductor devices.

The technology disclosed in DESCRIPTION of this present application has been conceived in view of the aforementioned problems, and is a technology for suppressing variations in characteristics of a device which are caused by buried gate electrodes.

### Means to Solve the Problem

A nitride semiconductor device according to a first aspect of the technology disclosed in DESCRIPTION of this present application includes: a substrate; a first nitride semiconductor layer on an upper surface of the substrate; a second nitride semiconductor layer on an upper surface of the first nitride semiconductor layer; a source electrode on an upper surface of the second nitride semiconductor layer; a drain electrode on the upper surface of the second nitride semiconductor layer, the drain electrode being spaced from the source electrode; at least one blind hole between the source electrode and the drain electrode in a plan view, the at least one blind hole reaching an interior of the first nitride semiconductor layer from the upper surface of the second nitride semiconductor layer; a buried gate electrode inside the blind hole; and a gate finger electrode across an upper surface of the buried gate electrode and the upper surface of the second nitride semiconductor layer, wherein a side surface of the blind hole is along a {1 −1 00} plane of the first nitride semiconductor layer.

### Effects of the Invention

According to at least the first aspect of the technology disclosed in DESCRIPTION of this present application, forming the side surface of the blind hole along the {1 −1 0 0} plane can produce a flat and homogeneous side surface of a nitride semiconductor layer. This can make the interface properties between the buried gate electrodes and the side surface of the nitride semiconductor layer uniform, and suppress variations in characteristics of a device which are caused by precision variations in making holes.

The object, features, aspects, and advantages related to the technology disclosed in DESCRIPTION of this present application will become more apparent from the following detailed description and the accompanying drawings.

### BRIEF DESCRIPTION OF DRAWINGS

FIG. 1 is a perspective view illustrating an example structure of a nitride semiconductor device according to an embodiment.

FIG. 2 is a cross-sectional view corresponding to the cross-section A-A′ of the nitride semiconductor device illustrated in FIG. 1.

FIG. 3 is a cross-sectional view corresponding to the cross-section B-B′ of the nitride semiconductor device illustrated in FIG. 1.

FIG. 4 is a cross-sectional view corresponding to the cross-section C-C′ of the nitride semiconductor device illustrated in FIG. 1.

FIG. 5 is a cross-sectional view illustrating a modification corresponding to the cross-section C-C′ of the nitride semiconductor device illustrated in FIG. 1.

FIG. 6 is a cross-sectional view illustrating a modification corresponding to the cross-section C-C′ of the nitride semiconductor device illustrated in FIG. 1.

FIG. 7 is a flowchart illustrating an example method of manufacturing the nitride semiconductor device according to the embodiment.

FIG. 8 is a perspective view illustrating an example step of forming a nitride semiconductor layer and a nitride semiconductor layer on a main surface of a substrate.

FIG. 9 is a perspective view illustrating an example step of forming a mask on an upper surface of a nitride semiconductor layer.

FIG. 10 is a perspective view illustrating an example step of forming a formation region of buried gate electrodes.

FIG. 11 is a perspective view illustrating an example step of forming a source electrode and a drain electrode.

FIG. 12 is a perspective view illustrating an example step of forming the buried gate electrodes and a gate finger electrode.

FIG. 13 is a perspective view illustrating an example structure of a nitride semiconductor device according to an embodiment.

FIG. 14 is a cross-sectional view corresponding to the cross-section A-A′ of the nitride semiconductor device illustrated in FIG. 13.

FIG. 15 is a cross-sectional view corresponding to the cross-section B-B′ of the nitride semiconductor device illustrated in FIG. 13.

FIG. 16 is a cross-sectional view corresponding to the cross-section C-C′ of the nitride semiconductor device illustrated in FIG. 13.

### DESCRIPTION OF EMBODIMENTS

Embodiments will be hereinafter described with reference to the attached drawings. Although Embodiments will describe detailed features for description of the technology, they are mere exemplification and not necessarily essential features for making Embodiments feasible.

Note that the drawings are drawn in schematic form, and structures in the drawings are appropriately omitted or simplified for convenience of the description. The mutual relationships in size (horizontal and vertical dimensions) and position between structures in the different drawings are not necessarily accurate but may be changed when needed. The drawings such as plan views except cross-sectional views are sometimes hatched for facilitating the understanding of the details of Embodiments.

In the following description, the same reference numerals are assigned to the same constituent elements, and their names and functions are the same. Therefore, detailed description of such constituent elements may be omitted to avoid redundant description.

Unless otherwise specified, an expression “comprising”, “including”, or “having” a certain constituent element is not an exclusive expression for excluding the presence of the other constituent elements in DESCRIPTION of this present application.

Even when the ordinal numbers such as “first” and “second” are used in DESCRIPTION of this present application, these terms are used for convenience to facilitate the understanding of the details of Embodiments. The order indicated by these ordinal numbers does not restrict the details of Embodiments.

Unless otherwise specified, the expressions indicating equality, for example, “same”, “equal”, “uniform”, and “homogeneous” in DESCRIPTION of this present application include those indicating quantitatively exact equality and those in the presence of a difference within tolerance or to the extent that similar functions can be obtained.

In DESCRIPTION of this present application, when terms meaning a particular position and a particular direction such as “up”, “down”, “left”, “right”, “side”, “bottom”, “front”, or “back” are used, these are used for convenience to facilitate the understanding of the details of Embodiments, and need not always coincide with a position and a direction when Embodiments are actually implemented.

In DESCRIPTION of this present application, the expression of, for example, “an upper surface of” or “a lower surface of” a target element includes states where not only the upper surface or the lower surface of the element itself is formed but also another element is formed on the upper surface or the lower surface of the target element. Specifically, for example, the expression “B formed on the upper surface of A” does not prevent interposition of another element “C” between A and B.

In DESCRIPTION of this present application, a “nitride-based semiconductor” is a generic name for a semiconductor containing GaN, AlN, and InN and intermediate compositions thereof.

### Embodiment 1

A nitride semiconductor device and a method of manufacturing the nitride semiconductor device according to Embodiment 1 will be hereinafter described.

### [Structure of Nitride Semiconductor Device]

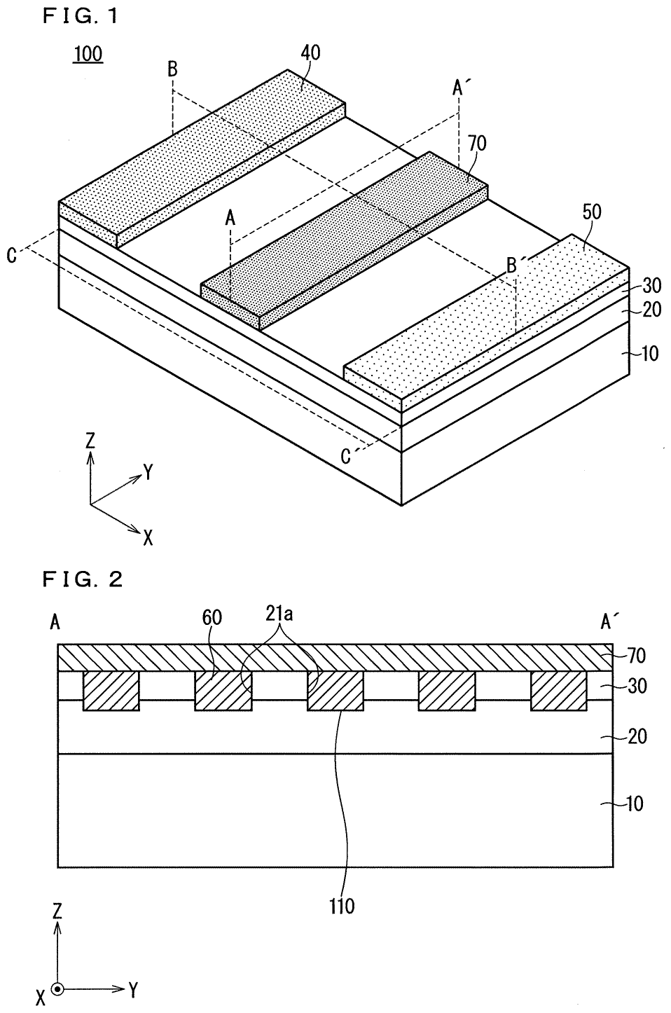

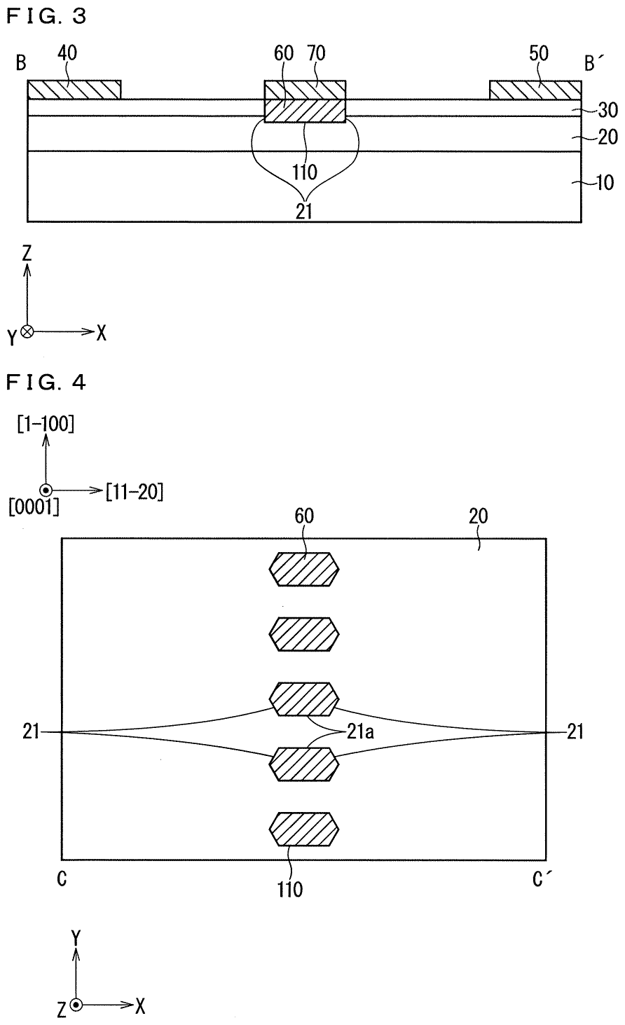

FIG. 1 is a perspective view illustrating an example structure of a nitride semiconductor device 100 according to Embodiment 1. Furthermore, FIG. 2 is a cross-sectional view corresponding to the cross-section A-A′ of the nitride semiconductor device 100 illustrated in FIG. 1. Furthermore, FIG. 3 is a cross-sectional view corresponding to the cross-section B-B′ of the nitride semiconductor device 100 illustrated in FIG. 1. Furthermore, FIG. 4 is a cross-sectional view corresponding to the cross-section C-C′ of the nitride semiconductor device 100 illustrated in FIG. 1.

As illustrated in the examples of FIGS. 1 to 4, the nitride semiconductor device 100 according to Embodiment 1 includes a substrate 10, a nitride semiconductor layer 20 on an upper surface of the substrate 10, a nitride semiconductor layer 30 on an upper surface of the nitride semiconductor layer 20, a source electrode 40 on an upper surface of the nitride semiconductor layer 30, a drain electrode 50 on the upper surface of the nitride semiconductor layer 30, the drain electrode 50 being spaced from the source electrode 40, a plurality of buried gate electrodes 60 penetrating the nitride semiconductor layer 30 between the source electrode 40 and the drain electrode 50 and formed such that bottoms are in contact with the nitride semiconductor layer 20, and a gate finger electrode 70 across an upper surface of the plurality of buried gate electrodes 60 and the upper surface of the nitride semiconductor layer 30.

To form the buried gate electrodes 60, at least one blind hole 110 reaching the interior of the nitride semiconductor layer 20 from the upper surface of the nitride semiconductor layer 30 is formed. A plurality of the blind holes 110 is formed in Embodiment 1. The buried gate electrodes 60 are formed by filling the blind holes 110.

The side surfaces of the blind holes 110 formed in this nitride semiconductor layer 20 (i.e., planes 21a in FIG. 2 and planes 21 in FIG. 3) are planes along an m-plane ({1 −1 0 0} plane) of the nitride semiconductor layer 20. The m-plane ({1 −1 0 0} plane) is a generic name for planes equivalent to (1 −1 0 0). In other words, the m-plane ({1 −1 0 0} plane) includes six planes of a (1 −1 0 0) plane, a (−1 1 0 0) plane, a (1 0 −1 0) plane, a (−1 0 1 0) plane, a (0 1 −1 0) plane, and a (0 −1 1 0) plane.

A semiconductor material such as Si, SiC, GaAs, GaN, AlN, InP, or α-Ga₂O₃ or an insulating material such as Al₂O₃, MgO, or diamond can be used in the substrate 10.

The nitride semiconductor layer 20 is made of a nitride semiconductor material with a wurtzite crystalline structure, for example, GaN. The nitride semiconductor layer 20 has a film thickness of, for example, 1 μm.

The nitride semiconductor layer 30 is made of, for example, AlₓGa₁₋ₓN. The nitride semiconductor layer 20 has a film thickness of, for example, 20 nm. A heterojunction can be formed as the nitride semiconductor layer 30, using a material with a band gap larger than that of the nitride semiconductor layer 20. For example, 2-dimensional electron gas at a high density can be generated in an interface between the nitride semiconductor layer 20 and the nitride semiconductor layer 30, using GaN in the nitride semiconductor layer 20 and AlₓGa₁₋ₓN in the nitride semiconductor layer 30. Thus, a nitride semiconductor device using the 2-dimensional electron gas as a channel can be formed.

The blind holes 110 for forming the buried gate electrodes 60 are made from the upper surface of the nitride semiconductor layer 30 to the interior of the nitride semiconductor layer 20.

Although FIG. 4 illustrates a hexagonal cross-sectional shape as an example cross-sectional shape of the blind hole 110 in a plan view, the cross-sectional shape need not always be a hexagon as long as the planes 21 and the planes 21a are m-planes of the nitride semiconductor layer 20.

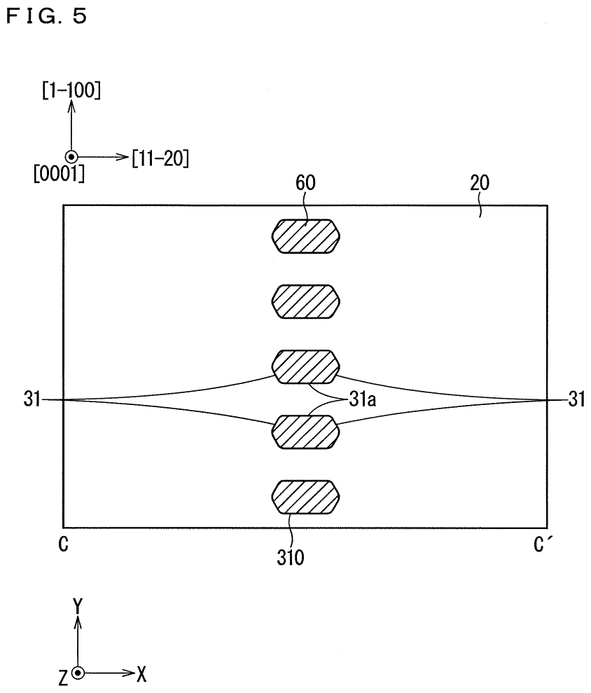

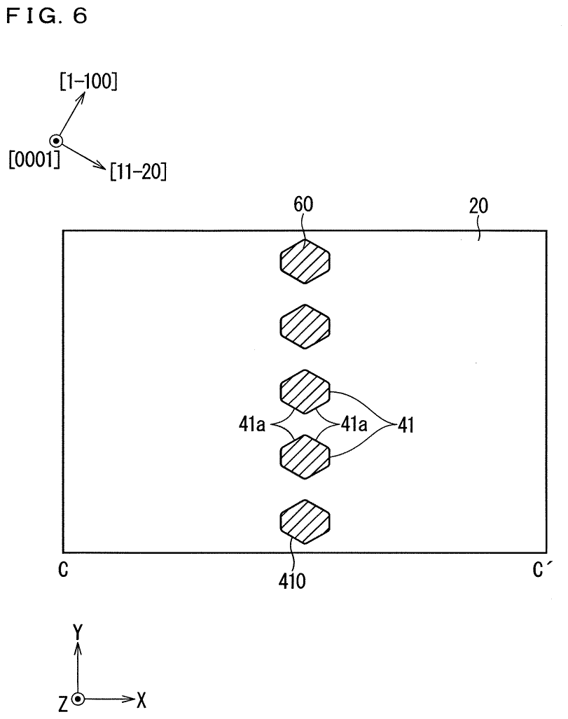

FIGS. 5 and 6 are cross-sectional views each illustrating a modification corresponding to the cross-section C-C′ of the nitride semiconductor device 100 illustrated in FIG. 1.

Although FIG. 4 illustrates that the planes 21 form an angular surface (i.e., an angular shape in a plan view), the blind hole may have a shape of a blind hole 310 in FIG. 5 or a shape of a blind hole 410 in FIG. 6. Specifically, as the example illustrated in FIG. 5, when planes sandwiched between the plurality of buried gate electrodes 60 in the blind holes 310 have a planar shape as planes 31a and planes that are not sandwiched between the plurality of buried gate electrodes 60 have a planar shape with corners as the planes 31, each of an intersection between the plane 31a and the plane 31 (i.e., a corner) and a corner of the planes 31 may have a round curved shape in a plan view. Furthermore, as the example illustrated in FIG. 6, when planes sandwiched between the plurality of buried gate electrodes 60 in the blind holes 410 have a planar shape with corners as planes 41a and planes that are not sandwiched between the plurality of buried gate electrodes 60 have a planar shape as the planes 41, each of an intersection between the plane 41a and the plane 41 (i.e., a corner) and a corner of the planes 41a may have a round curved shape in a plan view.

The buried gate electrodes 60 penetrate the nitride semiconductor layer 30 and exist partway in the nitride semiconductor layer 20 to fill the blind holes 110 in the nitride semiconductor layer 20. The bottom of each of the buried gate electrodes 60 is closer to the substrate 10 than the interface between the nitride semiconductor layer 20 and the nitride semiconductor layer 30 only by, for example, 50 nm.

Although FIG. 4 illustrates an example where the buried gate electrodes 60 are in contact with all planes of the planes 21 and the planes 21a, the buried gate electrodes 60 should be in contact with the planes sandwiched between the buried gate electrodes 60, and need not be in contact with the planes that are not sandwiched between the buried gate electrodes 60 (e.g., the planes 21 in FIG. 4).

Although the buried gate electrodes 60 are spaced at uniform intervals in FIG. 4 as an example, the intervals between the buried gate electrodes 60 need not be constant. The intervals between the buried gate electrodes 60 in FIG. 4 is, for example, 200 nm.

The buried gate electrode 60 forms a Schottky junction with each of the nitride semiconductor layer 20 and the nitride semiconductor layer 30. The buried gate electrodes 60 are made of, for example, a compound containing a metal, an alloy, a metal, and a semiconductor, or a semiconductor material doped with impurities. Examples of the metals used in the buried gate electrodes 60 include Ti, W, Ni, and Pt.

The gate finger electrode 70 is formed to connect the plurality of buried gate electrodes 60 as illustrated in FIG. 2. As illustrated in FIG. 3, the gate finger electrode 70 is formed in contact with the upper surface of the nitride semiconductor layer 30. In this case, the channel of the nitride semiconductor device 100 is formed in the interface between the nitride semiconductor layer 20 and the nitride semiconductor layer 30. This channel is controlled by the electric field from the buried gate electrodes 60 in the Y-axis direction and by the electric field from the gate finger electrode 70 in the Z-axis direction.

Air gaps may be provided between the gate finger electrode 70 and the nitride semiconductor layer 30. In this case, the channel of the nitride semiconductor device 100 is controlled only by the electric field from the buried gate electrodes 60 in the Y-axis direction. The gate finger electrode 70 is made of, for example, a compound containing a metal in Ohmic contact with the buried gate electrodes 60, an alloy, a metal, and a semiconductor, or a semiconductor material doped with impurities. Examples of the metals include Ti, W, Ni, and Pt.

The source electrode 40 and the drain electrode 50 are formed on the nitride semiconductor layer 30 such that the source electrode 40 and the drain electrode 50 are spaced from the gate finger electrode 70. The source electrode 40 and the drain electrode 50 are made of, for example, a compound containing a metal, an alloy, a metal, and a semiconductor, or a semiconductor material doped with impurities. Examples of the metals used in the source electrode 40 and the drain electrode 50 include Al, Nb, and Pd.

### [Method of Manufacturing Nitride Semiconductor Device]

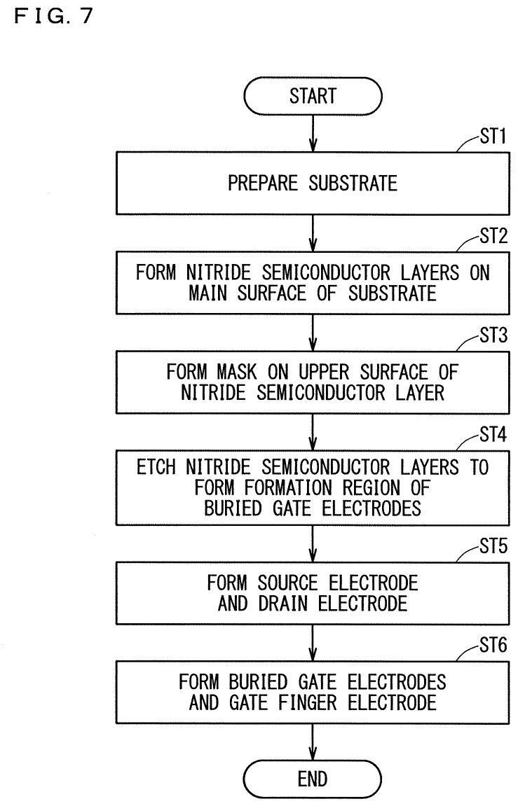

FIG. 7 is a flowchart illustrating an example method of manufacturing the nitride semiconductor device 100 according to Embodiment 1.

As illustrated in the example of FIG. 7, first, the substrate 10 is prepared in Step ST1. For example, the substrate 10 is a 4H-SiC substrate with a wurtzite structure, and its main surface is a (0 0 0 1) plane.

Next, the nitride semiconductor layer 20 and the nitride semiconductor layer 30 are formed on the main surface of the substrate 10 by, for example, metal organic chemical vapor deposition (MOCVD) in Step ST2.

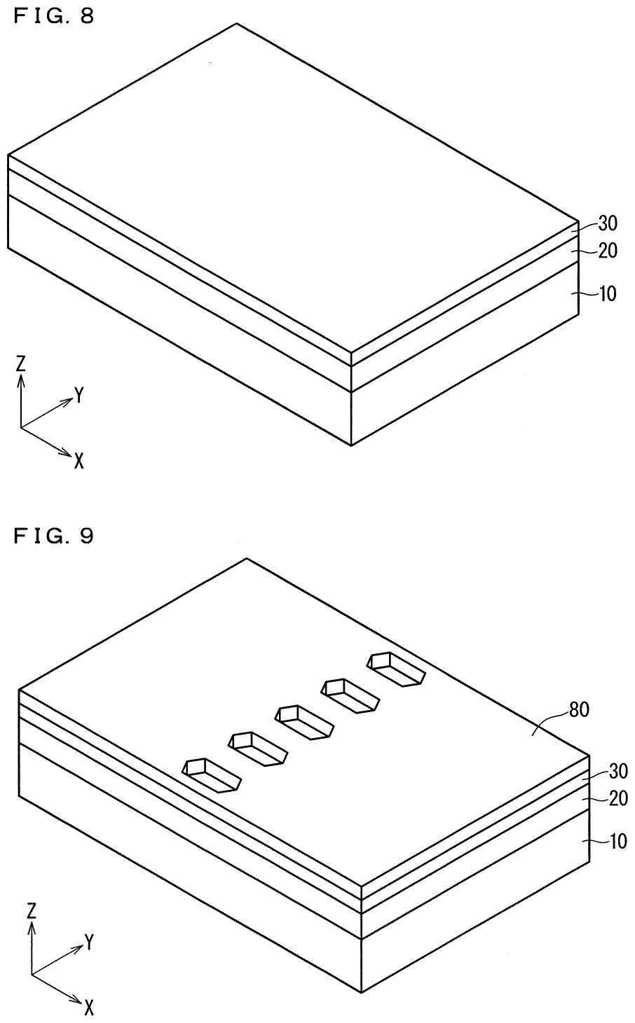

FIG. 8 is a perspective view illustrating an example step of forming the nitride semiconductor layer 20 and the nitride semiconductor layer 30 on the main surface of the substrate 10. Since the nitride semiconductor layer 20 with a wurtzite structure is epitaxially grown on the main surface of the substrate 10 also with a wurtzite structure, the main surface of the nitride semiconductor layer 20 also becomes a (0 0 0 1) plane.

Next, a mask 80 is formed on the upper surface of the nitride semiconductor layer 30 in Step ST3.

FIG. 9 is a perspective view illustrating an example step of forming the mask 80 on the upper surface of the nitride semiconductor layer 30. The mask 80 is formed by, for example, the following step.

First, a mask material is formed on the upper surface of the nitride semiconductor layer 30. For example, a resist such as a photosensitive resin is applied as the mask material to the upper surface of the nitride semiconductor layer 30. Example application methods include spin coating.

Next, the mask 80 is formed by opening the resist in a portion corresponding to a region for forming the buried gate electrodes 60, through a photolithography technique such as optical exposure or electron beam exposure.

The mask 80 may contain, for example, an electrical insulator such as SiO or SiN, or a metal such as Ti or Ni. In this case, the mask 80 is formed by patterning a mask material such as an electrical insulator or a metal, using a resist.

Methods of forming an electrical insulator or a metal mask material include plasma-enhanced chemical vapor deposition (PECVD) and physical vapor deposition such as vapor deposition and sputtering. Next, a resist such as a photosensitive resin is applied to the mask material. Example methods of applying the resist include spin coating. Next, the resist in the region for forming the buried gate electrodes 60 is opened by the photolithography technique such as optical exposure or electron beam exposure. Then, a hardmask material in the region for forming the buried gate electrodes 60 is opened by reactive-ion etching (RIE). Next, the mask 80 is formed by removing the resist, for example, by ashing using oxygen plasma or through solution processing using, for example, an organic solvent.

Next, the nitride semiconductor layer 30 and the nitride semiconductor layer 20 are etched to form the region for forming the buried gate electrodes 60 (a formation region of the buried gate electrodes 60) in Step ST4.

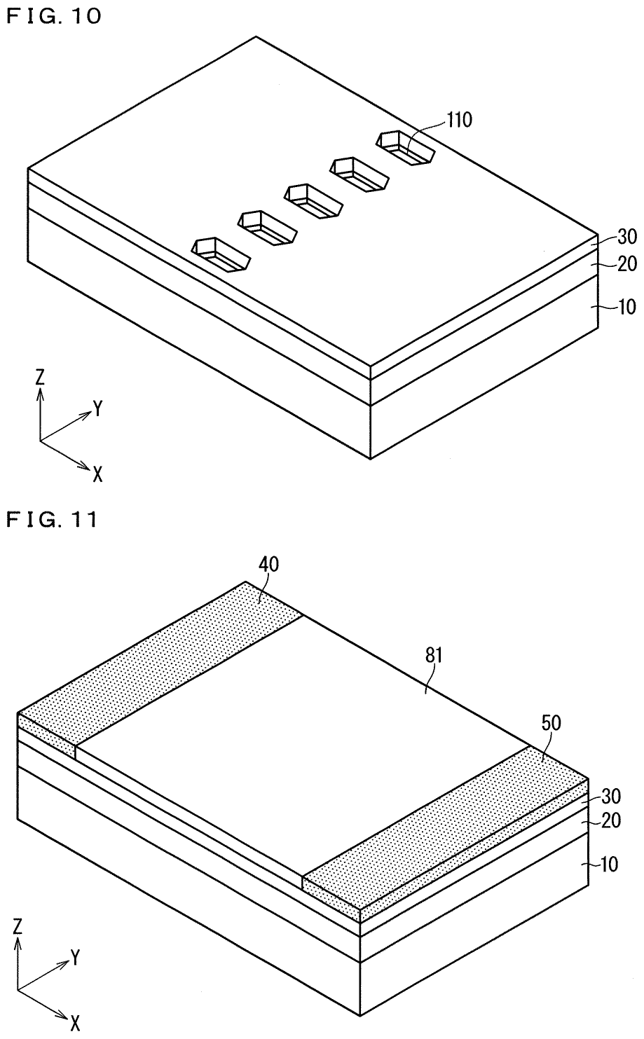

FIG. 10 is a perspective view illustrating an example step of forming the formation region of the buried gate electrodes 60. As illustrated in the example of FIG. 10, a nitride semiconductor layer is etched through the mask 80. Example etching methods include reactive-ion etching (abbr., RIE) with chlorine gas, and photoelectrochemical (PEC) etching using a solution containing peroxydisulfate ion and ultraviolet light.

The shape of the opening of the mask 80 is, for example, hexagonal. After etching the nitride semiconductor layer 20, the m-planes of the nitride semiconductor layer 20 are exposed on the side surfaces in the blind holes 110.

When the shape of the opening of the mask 80 is rectangular or circular, planes except the m-planes are exposed on the side surfaces in the openings. Here, wet etching using, for example, aqueous tetramethylammonium hydroxide heated to 80° C. after etching can expose the m-planes of the nitride semiconductor layer 20. This is because a nitride semiconductor with a wurtzite structure has an anisotropy on chemical resistance against a strong alkaline solution, and the etch rate of the m-plane is the lowest.

Next, the source electrode 40 and the drain electrode 50 are formed in Step ST5. FIG. 11 is a perspective view illustrating an example step of forming the source electrode 40 and the drain electrode 50. As illustrated in the example of FIG. 11, a mask 81 with openings corresponding to regions in which the source electrode 40 and the drain electrode 50 are formed is formed on the upper surface of the nitride semiconductor layer 30. Then, metal films to be the source electrode 40 and the drain electrode 50 are formed through the mask 81. The metal films are formed by, for example, vapor deposition.

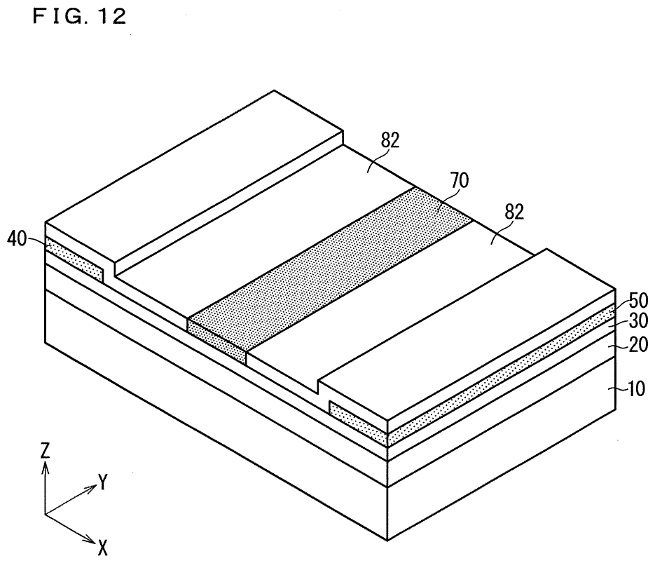

Next, the buried gate electrodes 60 and the gate finger electrode 70 are formed in Step ST6. FIG. 12 is a perspective view illustrating an example step of forming the buried gate electrodes 60 and the gate finger electrode 70. As illustrated in the example of FIG. 12, a mask 82 with an opening corresponding to a region in which the buried gate electrodes 60 and the gate finger electrode 70 are formed is formed on the upper surface of the nitride semiconductor layer 30. Then, a metal film to be the buried gate electrodes 60 and the gate finger electrode 70 is formed through the mask 82. The metal film is formed by, for example, vapor deposition.

In the nitride semiconductor device 100 with the buried gate electrodes 60, the nitride semiconductor layer 30 to be a channel is not only in contact with the gate finger electrode 70 on its upper surface but also in contact with the buried gate electrodes 60 on its side surface. Furthermore, the nitride semiconductor layer 20 to be a channel is in contact with the buried gate electrodes 60 on its side surface.

In other words, the channel formed in the interface between the nitride semiconductor layer 20 and the nitride semiconductor layer 30 in the nitride semiconductor device 100 is controlled not only by the electric field from the gate finger electrode 70 located on the upper surface of the channel, but also by the electric field from the buried gate electrodes 60 located on the side surface of the channel.

When a channel is controlled only by the electric field of gate electrodes on the upper surface of which the channel is located and the gate electrodes are downsized, the controllability of the channel decreases. Moreover, influences on the short channel effects such as an increase in the leakage current between the source electrode and the drain electrode, reduction in subthreshold characteristics, or changes in threshold voltage caused by the drain voltage become prominent.

In contrast, as seen in the nitride semiconductor device 100 according to Embodiment 1, the channel can be controlled by electric fields from three directions with additional channel control by the electric field of the buried gate electrodes 60 located on the side surface of the channel. Thus, the controllability of the channel will be improved, and the influences on the short channel effects can be reduced.

In a semiconductor device, characteristics of an interface between a semiconductor layer and a gate electrode affect characteristics of the semiconductor device, such as a threshold voltage and the subthreshold characteristics.

In the nitride semiconductor device including the buried gate electrodes 60, the gate finger electrode 70 is in contact with the upper surface of the nitride semiconductor layer 30 and the buried gate electrodes 60 are in contact with the side surfaces of the nitride semiconductor layer 20 and the nitride semiconductor layer 30. In other words, it is important to control not only interface properties between the upper surface of the nitride semiconductor layer 30 and the gate finger electrode 70 but also interface properties between the side surface of the nitride semiconductor layer 30 (the nitride semiconductor layer 20) and the buried gate electrodes 60, in the nitride semiconductor device including the buried gate electrodes 60.

The process of etching a semiconductor material depends on chemical and physical properties of a surface of the semiconductor material. The chemical and physical properties of the semiconductor material are changed according to an atomic arrangement on the surface, and the atomic arrangement on the surface differs depending on a crystal plane.

As described in Step ST4, holes are vertically formed on the c-plane that is a main surface of the nitride semiconductor layer 20 and the nitride semiconductor layer 30 to form a structure of the buried gate electrodes 60 in the nitride semiconductor device including the buried gate electrodes 60. Here, making holes using differences in chemical properties between crystal planes of the nitride semiconductor so that the m-planes of the nitride semiconductor layer 20 are exposed can produce a flat and homogeneous side surface of the nitride semiconductor layer. In addition, in wet etching after making holes as described in Step ST4, wet etching the nitride semiconductor layer 20 so that the m-planes of the nitride semiconductor layer 20 are exposed can produce a flat and homogeneous side surface of the nitride semiconductor layer.

Making the side surface of the nitride semiconductor layer flat and homogeneous can make the interface properties between the buried gate electrodes 60 and the side surface of the nitride semiconductor layer uniform.

Furthermore, since the nitride semiconductor device 100 includes the plurality of buried gate electrodes 60, the nitride semiconductor device 100 includes a plurality of interfaces between the side surface of the nitride semiconductor layer 30 (the nitride semiconductor layer 20) and the buried gate electrodes 60. Thus, making the interface properties between the side surface of the nitride semiconductor layer and each of the buried gate electrodes 60 uniform can make the characteristics of the nitride semiconductor device uniform, and suppress variations in the characteristics.

Here, roughness on the side surface of the nitride semiconductor layer 30 (the nitride semiconductor layer 20) easily creates small air gaps between the buried gate electrodes 60 and the side surface of the nitride semiconductor layer 30 (the nitride semiconductor layer 20). These air gaps may cause peeling off the buried gate electrodes 60 in manufacturing or using a semiconductor device.

Since the flat side surface of the nitride semiconductor layer 30 (the nitride semiconductor layer 20) can be obtained in the nitride semiconductor device 100, the adhesion between the buried gate electrodes 60 and the side surface of the nitride semiconductor layer 30 (the nitride semiconductor layer 20) can be improved, and occurrence of the small air gaps can be suppressed. Thus, manufacturing variability of nitride semiconductor devices can also be suppressed.

### Embodiment 2

A nitride semiconductor device and a method of manufacturing the nitride semiconductor device according to Embodiment 2 will be described. In the following description, the same reference numerals are assigned to the same constituent elements as those in Embodiment 1, and the detailed description will be appropriately omitted.

### [Structure of Nitride Semiconductor Device]

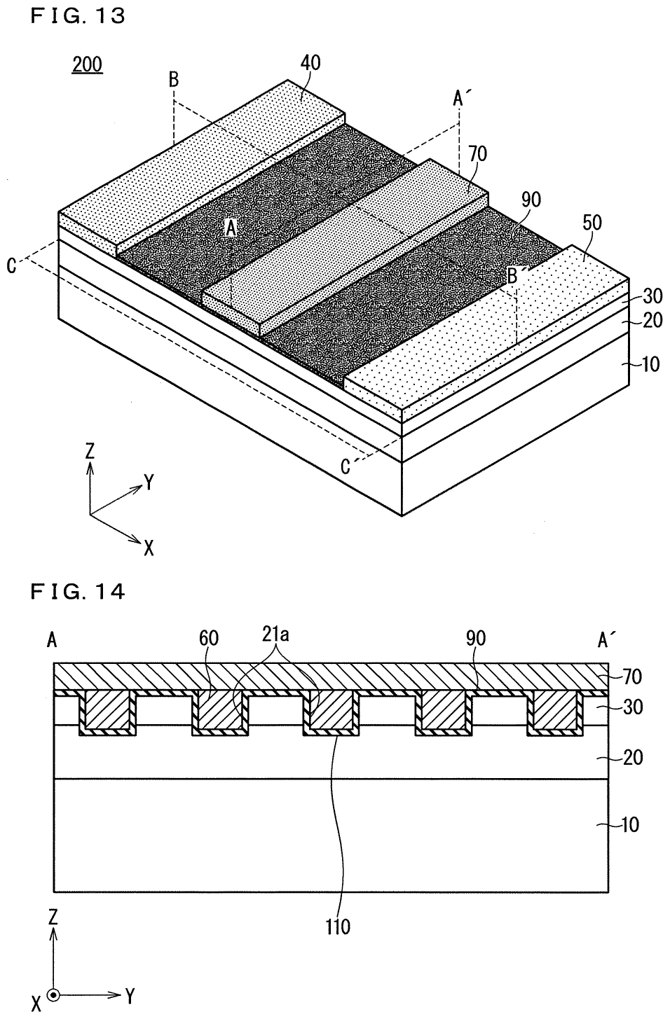

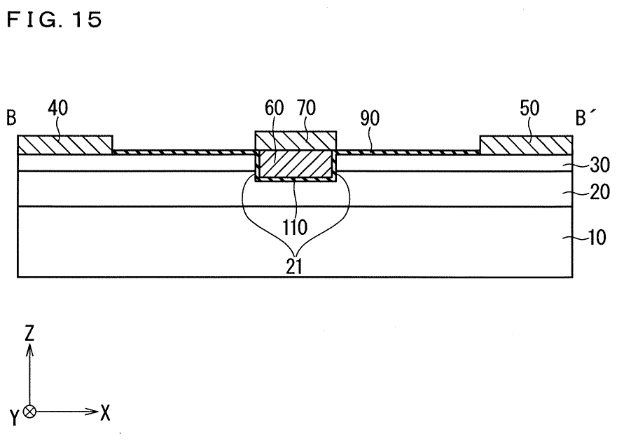

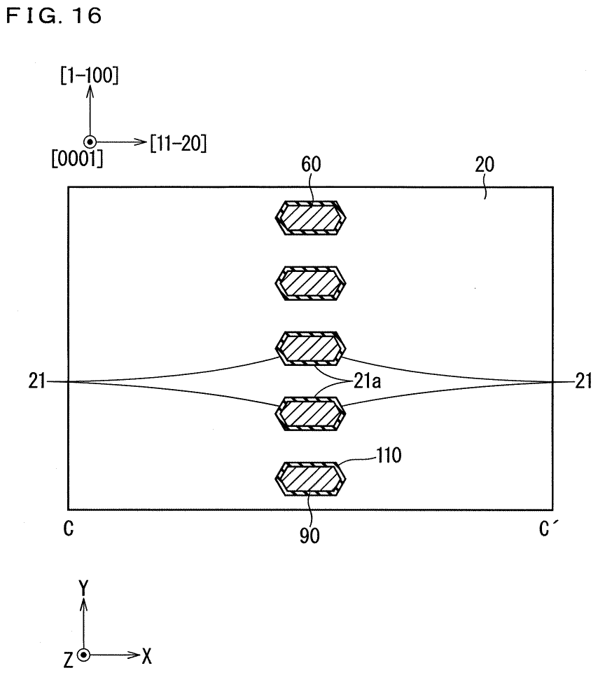

FIG. 13 is a perspective view illustrating an example structure of a nitride semiconductor device 200 according to Embodiment 2. Furthermore, FIG. 14 is a cross-sectional view corresponding to the cross-section A-A′ of the nitride semiconductor device 200 illustrated in FIG. 13. Furthermore, FIG. 15 is a cross-sectional view corresponding to the cross-section B-B′ of the nitride semiconductor device 200 illustrated in FIG. 13. Furthermore, FIG. 16 is a cross-sectional view corresponding to the cross-section C-C′ of the nitride semiconductor device 200 illustrated in FIG. 13.

As illustrated in the examples of FIGS. 13 to 16, the nitride semiconductor device 200 according to Embodiment 2 includes the substrate 10, the nitride semiconductor layer 20 on the upper surface of the substrate 10, the nitride semiconductor layer 30 on the upper surface of the nitride semiconductor layer 20, the source electrode 40 on the upper surface of the nitride semiconductor layer 30, the drain electrode 50 on the upper surface of the nitride semiconductor layer 30, the drain electrode 50 being spaced from the source electrode 40, the plurality of buried gate electrodes 60 penetrating the nitride semiconductor layer 30 between the source electrode 40 and the drain electrode 50 and formed such that bottoms are in contact with the nitride semiconductor layer 20, and the gate finger electrode 70 across the upper surface of the plurality of buried gate electrodes 60.

The nitride semiconductor device 200 according to Embodiment 2 further includes an insulating film 90 on a part of the upper surface of the nitride semiconductor layer 30 without the source electrode 40 and the drain electrode 50. The insulating film 90 is formed on interfaces between the buried gate electrodes 60 and the side surface of the nitride semiconductor layer 30 (side surfaces in the blind holes 110), interfaces between the buried gate electrodes 60 and the upper surface and the side surface of the nitride semiconductor layer 20 (side surfaces in the blind holes 110), and interfaces between the gate finger electrode 70 and the upper surface of the nitride semiconductor layer 30. The buried gate electrodes 60 fill the respective blind holes 110 through the insulating film 90.

The insulating film 90 should exist between the nitride semiconductor layer 30 and the buried gate electrodes 60 (i.e., the side surfaces in the blind holes 110), between the nitride semiconductor layer 20 and the buried gate electrodes 60 (i.e., the bottoms in the blind holes 110), and between the nitride semiconductor layer 30 and the gate finger electrode 70, and need not always cover the entire surface of the nitride semiconductor layer 30. The insulating film 90 is, for example, 5 nm in thickness. The insulating film 90 can be made of, for example, a metal oxide material such as SiO₂, Al₂O₃, HfO₂, Gd₂O₃, Ta₂O₃, or ZrO₂, a metal nitride material such as SiN or AlN, or a mixed crystal material of a metal oxide and a metal nitride.

The insulating film 90 is formed by, for example, the following method. In the flowchart illustrating the method of manufacturing the nitride semiconductor device in FIG. 7, a film made of an insulating material is formed by chemical vapor deposition (abbr., CVD) such as atomic layer deposition (abbr., ALD) on the upper surface and the side surface of the nitride semiconductor layer 20 exposed on the formation region of the buried gate electrodes 60, the side surface of the nitride semiconductor layer 30 exposed on the formation region of the buried gate electrodes 60, the upper surface of the nitride semiconductor layer 30, the upper surface of the source electrode 40, and the upper surface of the drain electrode 50 after Step ST5.

Then, the film made of the insulating material on the upper surface of the source electrode 40 and the upper surface of the drain electrode 50 is selectively removed by forming a mask pattern and etching using the mask.

The nitride semiconductor device 200 includes the insulating film 90 between the buried gate electrodes 60 and the nitride semiconductor layer 30 and the nitride semiconductor layer 20 to be a channel.

Without the insulating film 90, a nitride semiconductor layer forms a Schottky contact with the buried gate electrodes 60, so that a reverse leakage current passing a Schottky barrier flows when the channel is blocked, and a forward current flows when the channel is opened.

Here, forming the insulating film 90 with a high resistance between the nitride semiconductor layer and the buried gate electrodes 60 can increase the resistance between the nitride semiconductor layer and the buried gate electrodes 60, and reduce the current flowing between the nitride semiconductor layer and the buried gate electrodes 60.

Reduction in the current flowing between the nitride semiconductor layer and the buried gate electrodes 60 can reduce the loss of the semiconductor device, and improve the power efficiency.

### Advantages Produced by Embodiments Above

Next, advantages produced by Embodiments above will be described. Although the advantages will be described based on the specific structures whose examples are shown in Embodiments above, the structures may be replaced with another specific structure whose example is shown in DESCRIPTION of this present application as long as it produces the same advantages. Specifically, although only one of the specific structures is sometimes described as a representative for convenience, the structure may be replaced with another specific structure associated with the structure described as the representative.

Such replacement may be performed across a plurality of Embodiments. Specifically, such replacement may be performed when combined structures whose examples are described in different Embodiments produce the same advantages.

In Embodiments described above, a nitride semiconductor device includes the substrate 10, a first nitride semiconductor layer, a second nitride semiconductor layer, the source electrode 40, the drain electrode 50, at least one blind hole 110 (or the blind hole 310 or the blind hole 410), the buried gate electrodes 60, and the gate finger electrode 70. Here, the first nitride semiconductor layer corresponds to, for example, the nitride semiconductor layer 20. Furthermore, the second nitride semiconductor layer corresponds to, for example, the nitride semiconductor layer 30. The nitride semiconductor layer 20 is formed on the upper surface of the substrate 10. The nitride semiconductor layer 30 is formed on the upper surface of the nitride semiconductor layer 20. The source electrode 40 is formed on the upper surface of the nitride semiconductor layer 30. The drain electrode 50 is formed on the upper surface of the nitride semiconductor layer 30 such that the drain electrode 50 is spaced from the source electrode 40. The blind hole 110 is located between the source electrode 40 and the drain electrode 50 in a plan view. Furthermore, the blind hole 110 reaches the interior of the nitride semiconductor layer 20 from the upper surface of the nitride semiconductor layer 30. The buried gate electrode 60 is formed inside the blind hole 110. The gate finger electrode 70 is formed across the upper surface of the buried gate electrode 60 and the upper surface of the nitride semiconductor layer 30. Then, the side surface of the blind hole 110 is along a {1 −1 0 0} plane of the nitride semiconductor layer 20.

Such a structure of the side surface of the blind hole 110 along the {1 −1 0 0} plane can produce a flat and homogeneous side surface of a nitride semiconductor layer. This can make the interface properties between the buried gate electrodes 60 and the side surface of the nitride semiconductor layer uniform, and suppress variations in characteristics of a device which are caused by precision variations in making holes.

When the other structures whose examples are described in DESCRIPTION of this present application are appropriately added to the structure above, that is, the other structures in DESCRIPTION which are not mentioned as the structure above are appropriately added, the same advantages can be produced.

The nitride semiconductor layer 20 has a wurtzite crystalline structure according to Embodiments above. In this structure, a nitride semiconductor with a wurtzite structure has an anisotropy on chemical resistance against a strong alkaline solution, and the etch rate of the m-plane is the lowest. Thus, wet etching using, for example, aqueous tetramethylammonium hydroxide can expose the m-plane of the nitride semiconductor layer 20.

Furthermore, the blind hole 110 is hexagonal in a plan view according to Embodiments above. Such a structure having the side surface of the blind hole 110 as the m-plane can produce a flat and homogeneous side surface of a nitride semiconductor layer. This can make the interface properties between the buried gate electrodes 60 and the side surface of the nitride semiconductor layer uniform.

Furthermore, the blind hole 310 (or the blind hole 410) has a curved shape in a plan view according to Embodiments above. Such a structure can increase the flexibility of the shape of the blind hole.

The nitride semiconductor device includes the insulating film 90 covering at least a part of the nitride semiconductor layer 30 according to Embodiments above. Then, the insulating film 90 is formed between the nitride semiconductor layer 30 and the buried gate electrodes 60. Furthermore, the insulating film 90 is formed between the nitride semiconductor layer 20 and the buried gate electrodes 60. Furthermore, the insulating film 90 is formed between the nitride semiconductor layer 30 and the gate finger electrode 70. Such a structure can increase the resistance between a nitride semiconductor layer and the buried gate electrodes 60, and reduce the current flowing between the nitride semiconductor layer and the buried gate electrodes 60. Reduction in the current flowing between the nitride semiconductor layer and the buried gate electrodes 60 can reduce the loss of the semiconductor device, and improve the power efficiency.

In a method of manufacturing a nitride semiconductor device according to Embodiments above, the nitride semiconductor layer 20 is formed on the upper surface of the substrate 10. Then, the nitride semiconductor layer 30 is formed on the upper surface of the nitride semiconductor layer 20. Then, at least one blind hole 110 reaching the interior of the nitride semiconductor layer 20 from the upper surface of the nitride semiconductor layer 30 is formed. Then, the source electrode 40 is formed on the upper surface of the nitride semiconductor layer 30. Then, the drain electrode 50 is formed on the upper surface of the nitride semiconductor layer 30 such that the drain electrode 50 is spaced from the source electrode 40. Then, the buried gate electrode 60 is formed inside the blind hole 110. Then, the gate finger electrode 70 is formed across the upper surface of the buried gate electrode 60 and the upper surface of the nitride semiconductor layer 30. Here, the blind hole 110 is located between the source electrode 40 and the drain electrode 50 in a plan view. Furthermore, the side surface of the blind hole 110 is along a {1 −1 0 0} plane of the nitride semiconductor layer 20.

Such a structure of the side surface of the blind hole 110 along the {1 −1 0 0} plane can produce a flat and homogeneous side surface of a nitride semiconductor layer. This can make the interface properties between the buried gate electrodes 60 and the side surface of the nitride semiconductor layer uniform, and suppress variations in characteristics of a device which are caused by precision variations in making holes.

When there is no particular limitation, the order of processes can be changed.

When the other structures whose examples are described in DESCRIPTION of this present application are appropriately added, that is, the other structures in DESCRIPTION which are not mentioned as the structure above are appropriately added, the same advantages can be produced.

In a method of manufacturing a nitride semiconductor device according to Embodiments above, the insulating film 90 is formed on at least the side surface inside the blind hole 110. Then, the buried gate electrode 60 is formed inside the blind hole 110 through the insulating film 90. Such a structure can increase the resistance between the nitride semiconductor layer and the buried gate electrodes 60, and reduce the current flowing between the nitride semiconductor layer and the buried gate electrodes 60. Reduction in the current flowing between the nitride semiconductor layer and the buried gate electrodes 60 can reduce the loss of the semiconductor device, and improve the power efficiency.

### Modifications of Embodiments Above

Although Embodiments described above may specify materials, dimensions, shapes, relative arrangement relationships, and conditions for implementation of each of the constituent elements, these are examples in all aspects, and are not restrictive.

Therefore, numerous modifications and equivalents that have not yet been exemplified are devised within the scope of the technology disclosed in DESCRIPTION of this present application. Examples of the numerous modifications and equivalents include a case where at least one constituent element is modified, added, or omitted, and further a case where at least one constituent element in at least one embodiment is extracted and combined with a constituent element in another embodiment.

When at least one embodiment above specifies, for example, the name of a material without any particular designation, the material includes another additive, for example, an alloy unless it is contradictory.

Furthermore, when a constituent element is described as one element in Embodiments above, the number of the constituent elements may be more than one unless it is contradictory.

Furthermore, the constituent elements according to Embodiments above are conceptual units, and the scope of the technology disclosed in DESCRIPTION of this present application covers one constituent element comprising a plurality of structures, one constituent element corresponding to a part of a structure, and a plurality of constituent elements included in one structure.

Furthermore, each of the constituent elements in Embodiments above includes a structure having another structure or shape as long as it performs the same function.

DESCRIPTION of this present application is referred to for all the objectives of the present technology, and is not regarded as a conventional art.

### EXPLANATION OF REFERENCE SIGNS

10 substrate, 20 nitride semiconductor layer, 21 plane, 21a plane, 30 nitride semiconductor layer, 31 plane, 31a plane, 40 source electrode, 41 plane, 41a plane, 50 drain electrode, 60 buried gate electrode, 70 gate finger electrode, 90 insulating film, 100 nitride semiconductor device, 110 blind hole, 200 nitride semiconductor device, 310 blind hole, 410 blind hole, HEMT nitride semiconductor.

1. (canceled)

2. The nitride semiconductor device according to claim 3,
wherein the first nitride semiconductor layer has a wurtzite crystalline structure.

3. A nitride semiconductor device, comprising:
a substrate;
a first nitride semiconductor layer on an upper surface of the substrate;
a second nitride semiconductor layer on an upper surface of the first nitride semiconductor layer;
a source electrode on an upper surface of the second nitride semiconductor layer;
a drain electrode on the upper surface of the second nitride semiconductor layer, the drain electrode being spaced from the source electrode;
at least one blind hole between the source electrode and the drain electrode in a plan view, the at least one blind hole reaching an interior of the first nitride semiconductor layer from the upper surface of the second nitride semiconductor layer;
an embedded gate electrode inside the blind hole; and
a gate finger electrode across an upper surface of the embedded gate electrode and the upper surface of the second nitride semiconductor layer,
wherein a side surface of the blind hole is along a {1 −1 0 0} plane of the first nitride semiconductor layer, and
the blind hole is hexagonal in the plan view.

4. A nitride semiconductor device, comprising:
a substrate;
a first nitride semiconductor layer on an upper surface of the substrate;
a second nitride semiconductor layer on an upper surface of the first nitride semiconductor layer;
a source electrode on an upper surface of the second nitride semiconductor layer;
a drain electrode on the upper surface of the second nitride semiconductor layer, the drain electrode being spaced from the source electrode;
at least one blind hole between the source electrode and the drain electrode in a plan view, the at least one blind hole reaching an interior of the first nitride semiconductor layer from the upper surface of the second nitride semiconductor layer;
an embedded gate electrode inside the blind hole; and
a gate finger electrode across an upper surface of the embedded gate electrode and the upper surface of the second nitride semiconductor layer,
wherein a side surface of the blind hole is along a {1 −1 0 0} plane of the first nitride semiconductor layer, and
in the plan view, the blind hole has a corner, and the corner has a curved shape.

5. The nitride semiconductor device according to claim 3, further comprising
an insulating film covering at least a part of the second nitride semiconductor layer,
wherein the insulating film is formed between the second nitride semiconductor layer and the buried gate electrode, between the first nitride semiconductor layer and the buried gate electrode, and between the second nitride semiconductor layer and the gate finger electrode.

6. The nitride semiconductor device according to claim 3,
wherein the blind hole comprises a plurality of blind holes.

7. A method of manufacturing a nitride semiconductor device, comprising:
forming a first nitride semiconductor layer on an upper surface of a substrate;
forming a second nitride semiconductor layer on an upper surface of the first nitride semiconductor layer;
forming at least one blind hole reaching an interior of the first nitride semiconductor layer from an upper surface of the second nitride semiconductor layer;
forming a source electrode on the upper surface of the second nitride semiconductor layer;
forming a drain electrode on the upper surface of the second nitride semiconductor layer such that the drain electrode is spaced from the source electrode;
forming a buried gate electrode inside the blind hole; and
forming a gate finger electrode across an upper surface of the buried gate electrode and the upper surface of the second nitride semiconductor layer,
wherein the blind hole is located between the source electrode and the drain electrode in a plan view,
a side surface of the blind hole is along a {1 −1 0 0} plane of the first nitride semiconductor layer, and
the blind hole is hexagonal in the plan view.

8. The method according to claim 7, further comprising
forming an insulating film on at least the side surface inside the blind hole,
wherein the buried gate electrode is formed inside the blind hole through the insulating film.

9. The method according to claim 7,
wherein the blind hole comprises a plurality of blind holes.

10. The nitride semiconductor device according to claim 4,
wherein the first nitride semiconductor layer has a wurtzite crystalline structure.

11. The nitride semiconductor device according to claim 4, further comprising
an insulating film covering at least a part of the second nitride semiconductor layer,
wherein the insulating film is formed between the second nitride semiconductor layer and the embedded gate electrode, between the first nitride semiconductor layer and the embedded gate electrode, and between the second nitride semiconductor layer and the gate finger electrode.

12. The nitride semiconductor device according to claim 4,
wherein the blind hole comprises a plurality of blind holes.

13. A method of manufacturing a nitride semiconductor device, comprising:
forming a first nitride semiconductor layer on an upper surface of a substrate;
forming a second nitride semiconductor layer on an upper surface of the first nitride semiconductor layer;
forming at least one blind hole reaching an interior of the first nitride semiconductor layer from an upper surface of the second nitride semiconductor layer;
forming a source electrode on the upper surface of the second nitride semiconductor layer;
forming a drain electrode on the upper surface of the second nitride semiconductor layer such that the drain electrode is spaced from the source electrode;
forming an embedded gate electrode inside the blind hole; and
forming a gate finger electrode across an upper surface of the embedded gate electrode and the upper surface of the second nitride semiconductor layer,
wherein the blind hole is located between the source electrode and the drain electrode in a plan view,
a side surface of the blind hole is along a {1 −1 0 0} plane of the first nitride semiconductor layer, and
in the plan view, the blind hole has a corner, and the corner has a curved shape.

14. The method according to claim 13, further comprising
forming an insulating film on at least the side surface inside the blind hole,
wherein the embedded gate electrode is formed inside the blind hole through the insulating film.

15. The method according to claim 13,
wherein the blind hole comprises a plurality of blind holes.
